(19) United States
(12) Patent Application Publication
(10) Pub. No.: US 2017/0033039 A1
(43) Pub. Date: Feb. 2, 2017

(54) SEMICONDUCTOR PACKAGE AND METHOD OF MANUFACTURING THE SAME

(71) Applicant: SAMSUNG ELECTRO-MECHANICS CO., LTD., Suwon-si (KR)

(72) Inventors: Ki Ju LEE, Suwon-si (KR); Jun Woo MYUNG, Suwon-si (KR); No Il PARK, Suwon-si (KR); Jin Su KIM, Suwon-si (KR); Eung Suek LEE, Suwon-si (KR); Jae Hyun LIM, Suwon-si (KR)

(73) Assignee: SAMSUNG ELECTRO-MECHANICS CO., LTD., Suwon-si (KR)

(21) Appl. No.: 15/074,376

(22) Filed: Mar. 18, 2016

(30) Foreign Application Priority Data
Jul. 31, 2015 (KR) 10-2015-0109050

(51) Int. Cl. H01L 23/498; H01L 25/00; H01L 21/56; H01L 21/48; H01L 23/31; H01L 25/065

(52) U.S. Cl. CPC H01L 23/49861; H01L 23/49838; H01L 23/3121; H01L 25/0657; H01L 21/56; H01L 21/4825; H01L 25/50; H01L 2225/06524; H01L 2225/06572

(57) ABSTRACT

A semiconductor package includes a first substrate, a pattern layer disposed on the first substrate, a first chip member disposed on a surface of the first substrate, lead frames mounted on the first substrate surrounding the first chip member, and a first encapsulation layer disposed on the first substrate, encapsulating the first chip member and the lead frame, wherein upper end portions of the lead frame and the first encapsulation layer are removed, and lead frame columns are exposed through the first encapsulation layer.

### CROSS-REFERENCE TO RELATED APPLICATION

This application claims the under 35 USC 119(a) benefit of Korean Patent Application No. 10-2015-0109050, filed on Jul. 31, 2015 with the Korean Intellectual Property Office, the entire disclosure of which is incorporated herein by reference for all purposes.

### BACKGROUND

1. Field

The following description relates to a semiconductor package and a method of manufacturing the same.

2. Description of Related Art

Currently, in order to connect a top surface and a bottom surface to each other, or to form connection electrodes toward an outer portion of a package on a circuit board, a method of using a copper pin, or forming a via hole in a encapsulation layer and plating an inner portion of the via hole is mainly used.

However, in a case in which an interval between the connection electrodes is decreased at a fine pitch, there is a problem that both aligning and manufacturing the copper pin are difficult. The method of forming a via hole in an encapsulation layer and plating an inner portion of the via hole is also problematic in that a processing yield is decreased as a via hole is decreased at the fine pitch because a ratio of a diameter of the via hole to an axial length of the via hole is predetermined.

Further, since it is difficult to consistently form a constant axial length by the method of using a copper pin or plating an inner portion of a via hole, a structural change for forming the connection electrodes is desired.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor package includes a first substrate, a pattern layer disposed on the first substrate, a first chip member disposed on a surface of the first substrate, lead frames mounted on the first substrate surrounding the first chip member, and a first encapsulation layer disposed on the first substrate, encapsulating the first chip member and the lead frame, wherein upper end portions of the lead frame and the first encapsulation layer are removed, and lead frame columns are exposed through the first encapsulation layer.

A plurality of lead frames may be provided along four lateral sides of the first chip member.

The semiconductor package my further include a second substrate disposed on the first encapsulation layer, a second chip member disposed on the second substrate, and a second encapsulation layer, encapsulating the second substrate and the second chip member. The first substrate and the second substrate may be electrically connected to each other by a plurality of lead frame columns provided along four sides of the first chip member.

The semiconductor package may further include a second chip member disposed on another surface of the first substrate, opposite to the surface of the first substrate, and a second encapsulation layer, encapsulating the second chip member.

An upper end portion or a lower end portion, or both end portions, of the lead frame columns may include a bent part.

The semiconductor package may further include a solder part disposed on a top surface of the lead frame.

The semiconductor package may further include mounting electrodes disposed on the surface of the first substrate and another surface of the first substrate. The pattern layer may electrically connect to the mounting electrode on the surface of the first substrate to the mounting electrode disposed on the other surface of the first substrate.

In another general aspect, a method of manufacturing a semiconductor package includes preparing a first substrate, disposing a first chip member on a surface of the first substrate, disposing a lead frame on the surface of the first substrate along a side of the first chip member, disposing a first encapsulation layer onto the surface of the first substrate, wherein the first encapsulating layer encapsulates the first chip member and the lead frame, and removing upper end portions of the first encapsulation layer and the lead frame.

A plurality of lead frames may be connected to each other by a support. The support may be removed together with the upper end portion of the lead frame.

Upper end portions of the first encapsulation layer and the lead frame may be removed by polishing, grinding, or cutting.

An upper end portion, or a lower end portion, or both end portions of the lead frame may include a bent part.

After the removing of the upper end portions of the first encapsulation layer and the lead frame, the method may further include disposing a second substrate on the first encapsulation layer and the lead frame, disposing a second chip member on the second substrate, and disposing a second encapsulation layer, encapsulating the second chip member.

After the removing of the upper end portions of the first encapsulation layer and the lead frame, the method may further include disposing one or more second chip members onto another surface of the first substrate, and disposing a second encapsulation layer, encapsulating the second chip members.

The lead frame may be provided to form a plurality of columns adjacent to each lateral side of the first chip member.

After the removing of the upper end portions of the first encapsulation layer and the lead frame, the method may further include disposing a solder part on the lead frame.

The method may further include disposing mounting electrodes on the surface of the first substrate and another surface of the first substrate.

Other features and aspects will be apparent from the following detailed description, the drawings, and the claims.

### BRIEF DESCRIPTION OF DRAWINGS

FIG. 1 is a cross-sectional view illustrating a semiconductor package according to an embodiment;

FIG. 2 through 6 illustrate a method of manufacturing a semiconductor package according to an embodiment;

FIG. 3 is a view illustrating lead frames mounted on the semiconductor package;

FIG. 7 is a schematic cross-sectional view illustrating a semiconductor package according to another embodiment;

FIG. 8 is a schematic cross-sectional view illustrating a semiconductor package according to another embodiment; and

FIG. 9 is a schematic cross-sectional view illustrating a semiconductor package according to another embodiment.

FIG. 10 is a cross-sectional view illustrating a lead frame according to another embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the embodiments.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

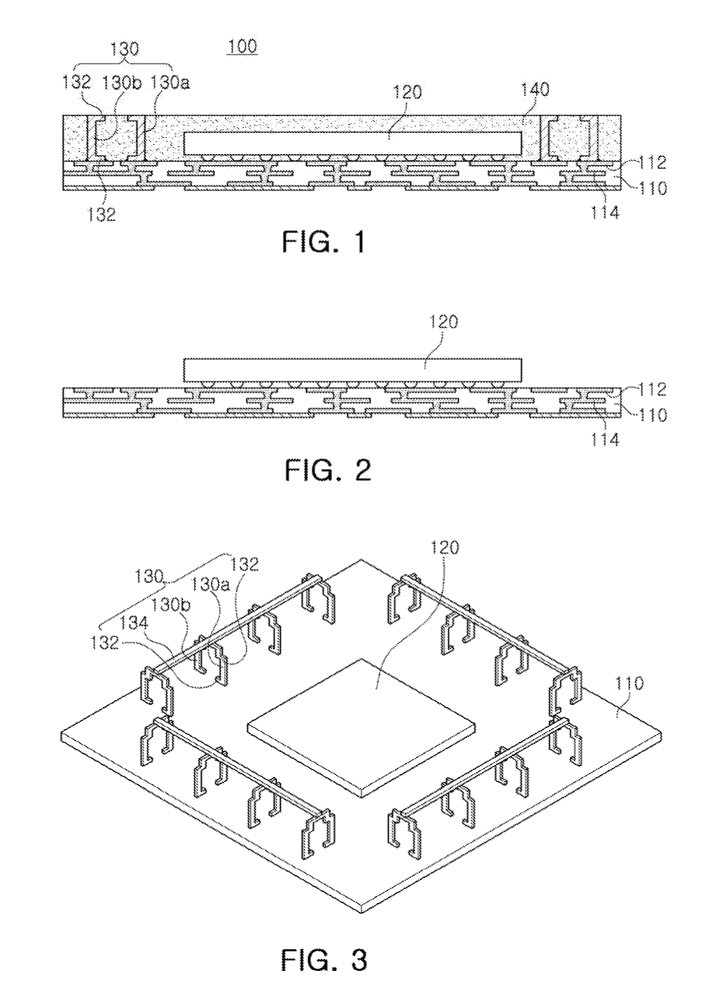

FIG. 1 is a cross-sectional view illustrating a semiconductor package according to an embodiment.

Referring to FIG. 1, a semiconductor package 100 includes a first substrate 110, a first chip member 120, a lead frame 130, and a first encapsulation layer 140.

The first substrate 110, is a configured to have the first chip member 120 mounted on at least one surface thereof. By way of example, the substrate may be any one of various kinds of substrates such as a ceramic substrate, a printed circuit board, or a flexible substrate.

Additionally, the first substrate 110 is a multilayer substrate having a plurality of layers, and a pattern layer 114 for forming an electrical connection is formed between the respective layers. In addition, the first substrate 110 also has a conductive via electrically connecting the mounting electrode 112 and the pattern layer 114 to each other. A first surface or a second surface, or both surfaces of the first substrate 110 includes a mounting electrode 112 for mounting the chip member. The pattern layer 114 electrically connects the mounting electrodes at the first surface to mounting electrodes at the second surfaces. The first surface includes an upper or top surface of the first substrate 110, and the second surface includes a lower or bottom surface of the first substrate 110.

The first chip member 120 is mounted on at least one surface of the first substrate 110, and includes various elements such as a passive element and an active element. As long as the element can be mounted on the first substrate 110, any element may be used as the first chip member 120. The first chip member 120 may be disposed on the at least one surface of the first substrate 110 in various forms depending on a size and a form of the first chip member 120, and a design of the semiconductor package 100. In addition, the first chip member 120 may be mounted on the first substrate 110 in a flip-chip form.

Referring to FIG. 1, the first chip member 120 is mounted on a top surface of the first substrate 110. However, the first chip member 120 is not limited to being mounted on the top surface of the first substrate 110, and may also be mounted on the top surface, or a bottom surface, of the first substrate 110. Additionally, a chip members 120 may be disposed on each of the top surface and the bottom surface of the first substrate 110.

In one or more embodiments, a lead frame 130 is mounted on the first substrate 110 and disposed on both sides of the first chip member 120, as shown in FIG. 1, or a lead frame 130 may be disposed along each lateral side of the first chip member. As an example, lead frames 130 are mounted on the first substrate 110 so as to surround the first chip member 120, as shown in FIG. 3.

The lead frames 130 form a plurality of columns at each side of the first chip member 120, and as an example, the lead frame 130 forms two columns 130a and 130b (see FIG. 1). In addition, the lead frame 130 includes bent parts 132 at an upper end portion and a lower end portion thereof. Since the above-mentioned bent parts 132 are included in the lead frame 130, a bonding area between the lead frame 130 and another component may be increased, thereby improving reliability.

After the lead frame 130 is mounted on the first substrate 110 and the first encapsulating layer is formed, the upper end portion of the lead frame 130 and an upper portion the first encapsulation layer 140 are removed to form the semiconductor package 100 illustrated in FIG. 1. In addition, the lead frame 130 may be a material having excellent thermal conductivity. As an example, the lead frame 130 may be formed of a copper material. As such, since the lead frame is formed by removing the upper end portion of the lead frame 130 after the lead frame 130 is mounted, the lead frame columns 130a and 130b having fine pitch may be easily formed. In other words, disposing the lead frame columns 130a and 130b extending substantially perpendicularly from the first substrate 110 may be easily achieved. Additionally, since the lead frame columns 130a and 130b are substantially perpendicular to each other, the distance between the columns 130a and 130b is reduce as compared to conventional semiconductor package having pins or through vias. Further, since the lead frame columns 130a and 130b are formed by a surface mounting process, a process yield may be improved.

The first encapsulation layer 140 may be laminated, or otherwise disposed, on the first substrate 110 so as to embed the first chip member 120 and the lead frame 130. That is, the first encapsulation layer 140 seals the first chip member 120 and the lead frame 130 mounted on the first substrate 110. In addition, the first encapsulation layer 140 is provided between the first chip member 120 and the lead frame 130 mounted on the first substrate 110, thereby preventing an occurrence of an electrical short circuit between the first chip member 120 and the lead frame 130. In addition, the first encapsulation layer 140 surrounds an outer portion of the first chip member 120 to fix the first chip member 120 on the first substrate 110. Thus, the first encapsulation layer 140 may prevent damage and detachment of the first chip member 120 due to external impact. The first encapsulation layer 140 may be formed of an insulating material including a resin material such as an epoxy, such as an epoxy molding compound (EMC).

After the first encapsulation layer 140 is disposed, the upper end portions of the first encapsulation layer 140 and the lead frame 130 are both removed, and thus the lead frame columns 130a and 130b are exposed through a top surface of the first encapsulation layer 140. As an example, an upper end portion of the first encapsulation layer 140 and the upper end portion of the lead frame 130 may be removed by polishing, grinding or cutting. As described above, the lead frame columns 130a and 130b are formed by removing the upper end portion of the lead frame 130 after the lead frames 130 are mounted. Further, since the lead frame 130 may be formed by the surface mounting process, the process yield may be improved.

Hereinafter, a method of manufacturing a semiconductor package according to an embodiment will be described with reference to the accompanying drawings.

FIGS. 2 through 6 illustrate a method of manufacturing a semiconductor package according to one or more embodiments, and FIG. 3 is a view illustrating a lead frame mounted on the semiconductor package.

First, referring to FIG. 2, a first chip member 120 is mounted on a first substrate 110. The first substrate 110 may be any one of various kinds of substrates such as a ceramic substrate, a printed circuit board, or a flexible substrate, by way of example.

In addition, one or two surfaces of the first substrate 110 may be provided with a mounting electrode 112 for mounting the chip member or a pattern layer 114 electrically connecting the mounting electrodes to each other with through vias. In addition, the first substrate 110 may be a multilayer substrate formed of a plurality of layers.

Additionally, the first chip member 120 may include various elements such as a passive element and an active element, and as long as the elements can be mounted on the first substrate 110, any element may be used as the first chip member 120. As an example, the first chip member 120 may be mounted on the first substrate 110 in a flip-chip form.

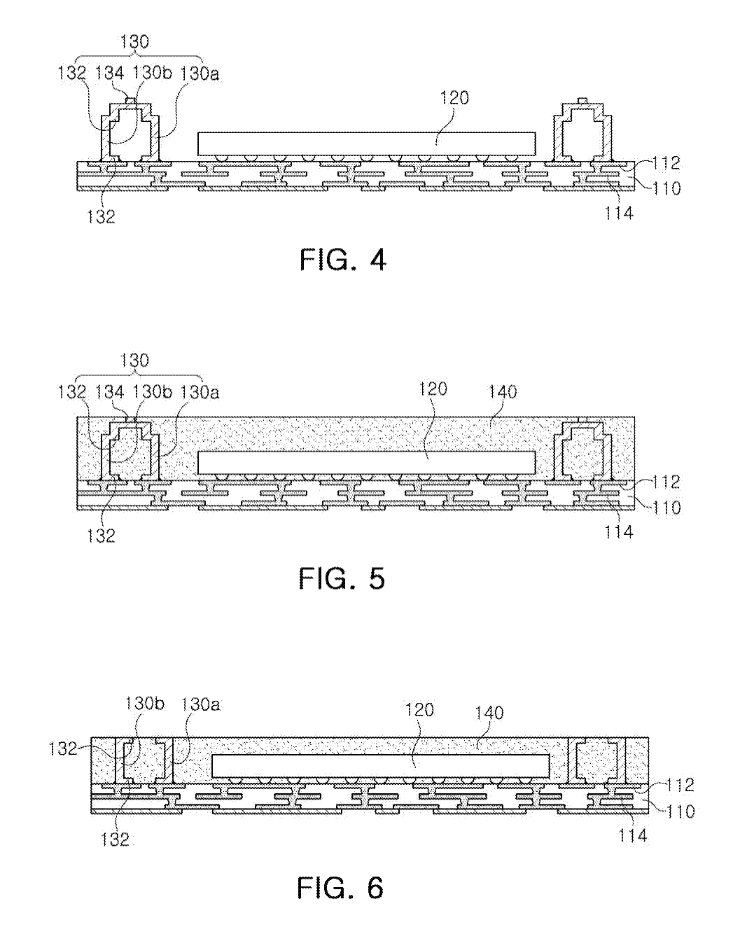

Referring to FIG. 4, a lead frame 130 is mounted on the first substrate 110, on two sides of the first chip member 120.

A row of lead frames 130 are connected to each other by a support 134 with the lead frame columns 130a and 130b disposed on two lower sides of the support 134. In addition, the lead frame 130 includes a bent portion 132 for increasing an adhering surface to be bonded to the first substrate 110. Thus, adhesion between the lead frame 130 and the first substrate 110 may be increased, thereby improving reliability. Additionally, a risk of a connection defect between the lead frame 130 and the first substrate 110 may be reduced. In addition, since the row of integrally formed lead frames 130, as illustrated in FIG. 3, is mounted on the first substrate 110, a process yield may be improved. Further, since the lead frame 130 is separately manufactured, disposing the lead frames columns 130a and 130b substantially perpendicular to the first substrate 110 may be achieved, thereby reducing a distance between the lead frame columns 130a and 130b as compared to conventional through vias.

Referring to FIG. 5, a first encapsulation layer 140 is laminated, or otherwise disposed, so as to embed the first chip member 120 and the lead frame 130. The first encapsulation layer 140 may be an insulating material including a resin material such as an epoxy, for example, an epoxy molding compound (EMC).

Referring to FIG. 6, an upper end portion of the lead frame 130, support 134 and upper end portion of the first encapsulation layer 140 are removed through polishing, grinding, or cutting. Here, the support 134 and upper end portion of the lead frame 130 are removed together with the first encapsulation layer 140 so that the bent part 132 is externally exposed. In addition, the upper end portion of the lead frame 130 as described above is removed, and thus the lead frame first column 130a and the lead frame second column 130b are separated from each other.

As described above, since the lead frame columns 130a and 130b are formed by removing the upper end portion of the lead frame 130 after the plurality of integrally formed lead frames 130 are mounted, the lead frame columns 130a and 130b may be disposed substantially perpendicular to the first substrate 110. Thus, a distance between the lead frame columns 130a and 130b may be reduced as compared to a conventional semiconductor package using vias or individually placed pins. Further, since the lead frame 130 is formed by the surface mounting process, the process yield may be improved.

Hereinafter, a modified semiconductor package according to another embodiment will be described with reference to the accompanying drawings.

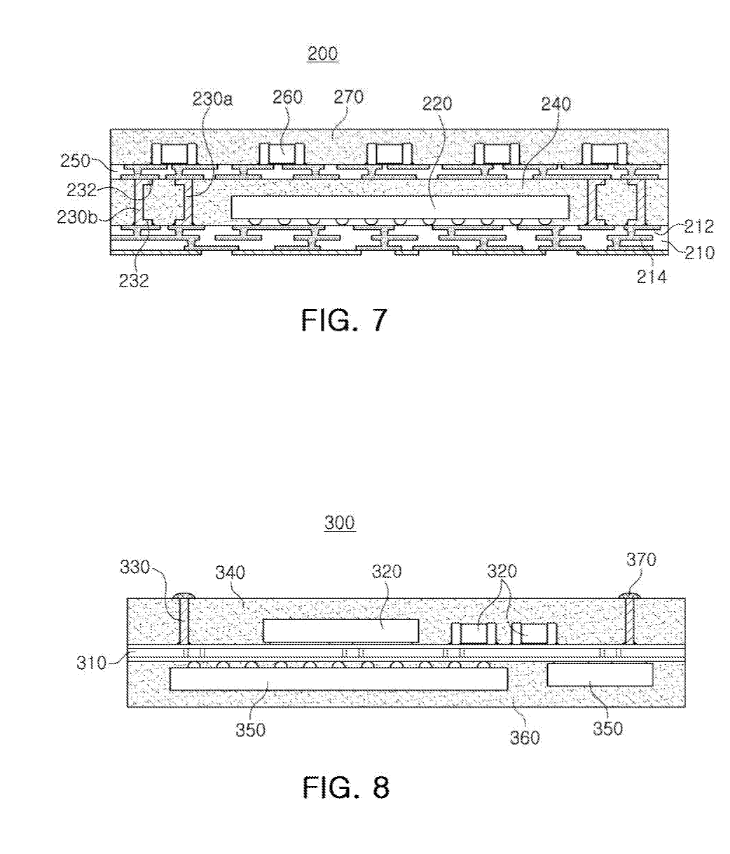

FIG. 7 is a schematic cross-sectional view illustrating a semiconductor package according to another embodiment.

Referring to FIG. 7, a semiconductor package 200, according to another embodiment, includes a first substrate 210, a first chip member 220, lead frame columns 230a and 230b, and a first encapsulation layer 240, a second substrate 250, a second chip member 260, and a second encapsulation layer 270. The first substrate 210, the first chip member 220, the lead frame columns 230a and 230b, and the first encapsulation layer 240 have substantially the same configurations as the first substrate 110, the first chip member 120, the lead frame columns 130a and 130b, and the first encapsulation layer 140 included in the semiconductor package 100 according to the embodiment described above.

The second substrate 250 may be laminated, or otherwise disposed, on the first encapsulation layer 240. The first substrate 210 and the second substrate 250 are electrically connected to each other by the lead frame columns 230a and 230b. In addition, since the lead frame columns 230a and 230b are provided with a bent part 232, an adhering area between the second substrate 250 and the lead frame 230 is increased, thereby reducing occurrences of a connection defect.

The second substrate 250, which has a configuration allowing a chip member to be mounted on at least one surface thereof, may be any one of various kinds of substrates such as a ceramic substrate, a printed circuit board, a flexible substrate, and the like, by way of example. The second substrate 250 may be a multilayer substrate formed of a plurality of layers, and the pattern layer for forming an electrical connection may be formed between desired layers. In addition, one surface or two surfaces of the second substrate 250 may also be provided with a mounting electrode for mounting the chip member or a pattern layer electrically connecting the mounting electrodes to each other.

The second chip member 260 is mounted on an upper surface of the second substrate 250. The second chip member 260 may include various elements such as a passive element and an active element, similar to the first chip member 220, and as long as the elements can be mounted on the second substrate 250, any element may be used as the second chip member 260.

In addition, in a case in which the first chip member 220 and the second chip member 260 are desired to be spaced apart from each other due to interference generated therebetween, the first chip member 220 may be mounted on the first substrate 210, and the second chip member 260 may be mounted on the second substrate 250. However, the arrangements of the first and second chip members 220 and 260 are not limited thereto, and may be varied depending on a desired spacing arrangement.

The second encapsulation layer 270 may be laminated, or otherwise disposed, on the second substrate 250 so as to embed the second chip member 260. That is, the second encapsulation layer 270 may seal the second chip member 260 mounted on the second substrate 250. In addition, the second encapsulation layer 270 is provided between a plurality of second chip members 260, in order to prevent an electrical short circuit between the second chip members 260.

In addition, the second encapsulation layer 270 surrounds an outer portion of the second chip member 260 to fix the second chip member 260 onto the second substrate 250 and simultaneously prevents damage and detachment of the second chip member 260 due to an external impact. The second encapsulation layer 270 may be formed of an insulating material including a resin material such as an epoxy, for example, an epoxy molding compound (EMC).

FIG. 8 is a schematic cross-sectional view illustrating a semiconductor package according to another embodiment.

Referring to FIG. 8, a semiconductor package 300 includes a first substrate 310, a first chip member 320, a lead frame 330, a first encapsulation layer 340, a second chip member 350, and a second encapsulation layer 360.

The first substrate 310, which has a configuration allowing the first and second chip members 320 and 350 to be mounted on upper and lower surfaces thereof, may be any one of various kinds of substrates such as a ceramic substrate, a printed circuit board, or a flexible substrate, for example only. Additionally, the first substrate 310 may be a multilayer substrate formed from a plurality of layers, and a circuit pattern for forming an electrical connection may be formed between desired layers. Further, the first substrate 310 may include conductive vias electrically connecting the mounting electrodes formed on both surfaces of the first substrate 310 and the circuit patterns formed therein to each other. In addition, the upper and lower surfaces of the first substrate 310 include mounting electrodes for mounting the first and second chip members 320 and 350, or wiring patterns electrically connecting the mounting electrodes to each other.

The first chip member 320 is mounted on the upper surface of the first substrate 310, and may include various elements such as a passive element and an active element. As long as the elements can be mounted on the first substrate 310, any element may be used as the first chip member 320. The first chip member 320 may have various sizes or shapes according to a desired semiconductor package 300, and the first chip member 320 may be mounted on the first substrate 310 by a conductive adhesive, for example.

The lead frames 330 are mounted on the first substrate 310 around a perimeter of the first chip member 320. As an example, the lead frames 330 surround the first chip member 320. As a further example, the lead frame 330 includes a column adjacent to each of the four sides of the first chip member 320. However, the lead frame 330 is not limited to being provided to form one column, and may also be provided to form a plurality of columns adjacent to each of the four sides of the first chip member 320. In addition, a solder part 370 for connection with external components may be laminated, or otherwise disposed, on a top surface of the lead frame 330.

The first encapsulation layer 340 may be laminated or otherwise disposed, on the first substrate 310 so as to encapsulate the first chip member 320 and the lead frame 330. That is, the first encapsulation layer 340 seals the first chip member 320 and the lead frame 330 mounted on the first substrate 310. In addition, the first encapsulation layer 340 is provided between the first chip member 320 and the lead frame 330 mounted on the first substrate 310, in order to prevent electrical short circuit between the first chip member 320 and the lead frame 330. In addition, the first encapsulation layer 340 surrounds an outer portion of the first chip member 320 to fix the first chip member 320 onto the first substrate 310. Thus, the first encapsulation layer 340 may prevent damage and detachment of the first chip member 320 due to external impact. The first encapsulation layer 340 may be an insulating material including a resin material such as an epoxy, for example, an epoxy molding compound (EMC).

After the first encapsulation layer 340 is disposed, upper end portions of the first encapsulation layer 340 and the lead frame 330 are both removed, and thus the lead frame 330 is exposed through a top surface of the first encapsulation layer 340. As an example, an upper end portion of the first encapsulation layer 340 and the upper end portion of the lead frame 330 may be removed by polishing, grinding or cutting.

The second chip member 350 is mounted on another surface of the first substrate 310, such as, a bottom surface of the first substrate 310. The second chip member 350 may also include various elements such as a passive element and an active element similar to the first chip member 120 and 220, and as long as the elements can be mounted on the first substrate 310, any element may be used as the second chip member 350.

In addition, in a case in which the first chip member 320 and the second chip member 350 are desired to be spaced apart from each other to prevent interference generated therebetween, the first chip member 320 may be mounted on one surface of the first substrate 310, and the second chip member 350 may be mounted on another surface of the first substrate 310. However, the arrangements of the first and second chip members 320 and 350 are not limited thereto, and may be varied according to a desired spacing arrangement.

The second encapsulation layer 360 may be laminated, or otherwise disposed, on the bottom surface of the first substrate 310 so as to encapsulate the second chip member 350. That is, the second encapsulation layer 360 seals the second chip member 350 mounted on the other surface of the first substrate 310. In addition, the second encapsulation layer 360 may be provided between a plurality of second chip members 350, thereby preventing an electrical short circuit between the second chip members 350. In addition, the second encapsulation layer 360 surrounds an outer portion of the second chip member 350 to fix the second chip member 350 onto the first substrate 310 and simultaneously prevent damage and detachment of the second chip member 350 due to an external impact. The second encapsulation layer 360 may be an insulating material including a resin material such as an epoxy, for example, an epoxy molding compound (EMC).

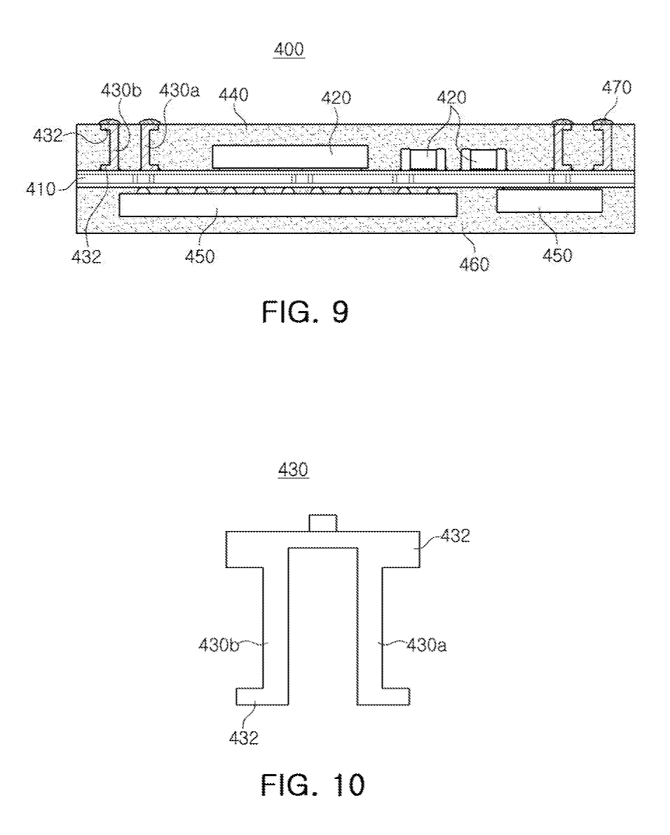

FIG. 9 is a schematic cross-sectional view illustrating a semiconductor package according to another embodiment. FIG. 10 is a cross-sectional view illustrating a lead frame according to another embodiment.

Referring to FIGS. 9 and 10, a semiconductor package 400 includes a first substrate 410, a first chip member 420, a lead frame 430, a first encapsulation layer 440, a second chip member 450, and a second encapsulation layer 460.

The first substrate 410, the first chip member 420, the first encapsulation layer 440, the second chip member 450, and the second encapsulation layer 460 of the semiconductor package 400 are similar to the first substrate 310, the first chip member 320, the first encapsulation layer 340, the second chip member 350, and the second encapsulation layer 360 of the semiconductor package 300 described above, respectively.

A lead frame 430 is mounted on the first substrate 410 along each lateral side of the first chip member 420. As an example, a plurality of lead frames 430 are mounted on the first substrate 410 surrounding the first chip member 420. The lead frames 430 include a plurality of columns disposed around four sides of the first chip member 420. For example, the lead frame 430 may be include two columns 430a and 430b. In addition, the lead frame 430 includes bent parts 432 at an upper end portion and a lower end portion thereof. The bent parts 432 increase an area of bonding between the lead frame columns 430a and 430b and another component, thereby improving reliability.

After the lead frame 430 is mounted onto the first substrate 410, the upper end portion of the lead frame 430 together with an upper end portion of the first encapsulation layer 440 are removed, resulting in a the semiconductor package 400 and lead frame columns 430a and 430b having a shape as illustrated in FIG. 9. In addition, the lead frame 430 may be formed of a material having excellent thermal conductivity. As an example, the lead frame 430 may be formed of a copper material, such as, copper.

As such, since the lead frame columns 430a and 430b are formed by removing the upper end portion of the lead frame 430 after the lead frame 430 is mounted, lead frame columns 430a and 430b is disposed onto the substrate 410 substantially perpendicular to the substrate 410. Thus, a distance between the lead frame columns 430a and 430b may be reduced as compared to a conventional semiconductor package using vias or individually placed pins. Further, since the lead frame columns 430a and 430b may be formed by a surface mounting process, a process yield may be improved.

As set forth above, according to one or more embodiments, lead frame columns may be perpendicularly disposed onto a substrate. Thus a distance between the lead frame columns may be reduced as compared to a conventional semiconductor package using vias or individually placed pins.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package, comprising:
a first substrate;
a pattern layer disposed on the first substrate;
a first chip member disposed on a surface of the first substrate;
lead frames disposed on the first substrate surrounding the first chip member; and
a first encapsulation layer disposed on the first substrate, encapsulating the first chip member and the lead frame,
wherein upper end portions of the lead frame and the first encapsulation layer are removed, and lead frame columns are exposed through the first encapsulation layer.

2. The semiconductor package of claim 1, wherein lead frames are provided along four lateral sides of the first chip member.

3. The semiconductor package of claim 1, further comprising:
a second substrate disposed on the first encapsulation layer;
a second chip member disposed on the second substrate; and
a second encapsulation layer, encapsulating the second substrate and the second chip member.

4. The semiconductor package of claim 3, wherein the first substrate and the second substrate are connected to each other by a plurality of lead frame columns provided along four sides of the first chip member.

5. The semiconductor package of claim 1, further comprising:
a second chip member disposed on another surface of the first substrate, opposite to the surface of the first substrate; and
a second encapsulation layer, encapsulating the second chip member.

6. The semiconductor package of claim 1, wherein an upper end portion or a lower end portion, or both end portions, of the lead frame columns comprise a bent part.

7. The semiconductor package of claim 1, further comprising:
a solder part disposed on a top surface of the lead frame.

8. The semiconductor package of claim 1, further comprising:
mounting electrodes disposed on the surface of the first substrate and another surface of the first substrate.

9. The semiconductor package of claim 8, wherein the pattern layer electrically connects the mounting electrode on the surface of the first substrate to the mounting electrode disposed on the other surface of the first substrate.

10. A method of manufacturing a semiconductor package, the method comprising:
preparing a first substrate;
disposing a first chip member on a surface of the first substrate;
disposing a lead frame on the surface of the first substrate along a side of the first chip member;
disposing a first encapsulation layer onto the surface of the first substrate, wherein the first encapsulating layer encapsulates the first chip member and the lead frame; and
removing upper end portions of the first encapsulation layer and the lead frame.

11. The method of claim 10, wherein lead frames are connected to each other by a support.

12. The method of claim 11, wherein the support is removed together with the upper end portion of the lead frame.

13. The method of claim 10, wherein upper end portions of the first encapsulation layer and the lead frame are removed by polishing, grinding, or cutting.

14. The method of claim 10, wherein an upper end portion, or a lower end portion, or both end portions of the lead frame comprise a bent part.

15. The method of claim 10, further comprising, after the removing of the upper end portions of the first encapsulation layer and the lead frame,
disposing a second substrate on the first encapsulation layer and the lead frame;
disposing a second chip member on the second substrate; and
disposing a second encapsulation layer, encapsulating the second chip member.

16. The method of claim 10, further comprising:
after the removing of the upper end portions of the first encapsulation layer and the lead frame,
disposing a second chip member onto another surface of the first substrate; and
disposing a second encapsulation layer, encapsulating the second chip members.

17. The method of claim 10, wherein the lead frame is provided to form a plurality of columns adjacent to each lateral side of the first chip member.

18. The method of claim 10, further comprising:
after the removing of the upper end portions of the first encapsulation layer and the lead frame:
disposing a solder part on the lead frame.

19. The method of claim 10, further comprising:
disposing mounting electrodes on the surface of the first substrate and another surface of the first substrate.
